(19) United States
(12) Patent Application Publication
(10) Pub. No.: US 2025/0332680 A1
(43) Pub. Date: Oct. 30, 2025

(54) DETERMINATION METHOD OF WAFER POLISHING CONDITIONS, METHOD OF MANUFACTURING WAFER, AND WAFER ONE SIDE POLISHING SYSTEM

(71) Applicant: SUMCO CORPORATION, Tokyo (JP)

(72) Inventors: Takeshi TAKAHASHI, Tokyo (JP); Yuji EGASHIRA, Tokyo (JP); Yuki NAKANO, Tokyo (JP)

(73) Assignee: SUMCO CORPORATION, Tokyo (JP)

(21) Appl. No.: 18/876,261

(22) PCT Filed: Apr. 13, 2023
(86) PCT No.: PCT/JP2023/014948

§ 371 Date: Dec. 18, 2024

(30) Foreign Application Priority Data
Jul. 4, 2022 (JP) 2022-107702

(51) Int. Cl. B24B 37/005; B24B 37/04; B24B 37/10

(52) U.S. Cl. CPC B24B 37/005; B24B 37/042; B24B 37/10

(57) ABSTRACT

A method of determining polishing conditions under which a wafer one side is polished by a polishing device including at least a surface plate, a polishing pad arranged on the surface plate, and a polishing chuck arranged above the polishing pad. The method includes setting a target range of a wafer polishing amount in-plane difference; determining a prediction range of a wafer polishing pressure in-plane difference predicted to be able to attain the wafer polishing amount in-plane difference within the target range on the basis of correlation between the wafer polishing amount in-plane difference and the wafer polishing pressure in-plane difference; and determining a pressing surface shape value range of the polishing chuck predicted to attain the wafer polishing pressure in-plane difference within the prediction range on the basis of correlation between the wafer polishing pressure in-plane difference and the pressing surface shape value of the polishing chuck.

### CROSS REFERENCE TO RELATED APPLICATIONS

This application claims the benefit of priority to Japanese Patent Application No. 2022-107702 filed on Jul. 4, 2022, which is expressly incorporated herein by reference in its entirety.

### TECHNICAL FIELD

The present invention relates to a determination method of wafer polishing conditions, a method of manufacturing a wafer, and a wafer one side polishing system.

### BACKGROUND ART

A device for polishing the surface of a wafer includes a one side polishing device and a both sides polishing device for polishing both sides of a wafer. With a one side polishing device, generally, while pressing a surface to be polished of a wafer held by a polishing chuck against a polishing pad bonded to a surface plate, in each of the polishing chuck and the surface plate are rotated, thereby bringing the surface to be polished of the wafer and the polishing pad into contact with each other. By supplying an abrasive to between the surface to be polished and the polishing pad thus coming in contact with each other, it is possible to polish the surface to be polished of the wafer (see, for example, Japanese Patent Application Publication No. 2007-274012 (the entire contents of which are herein incorporated by reference).

### SUMMARY OF INVENTION

In a wafer polishing step using a one side polishing device (which will be also hereinafter described as a “wafer one side polishing step”), within the plane of the surface to be polished of the wafer, a difference in polishing amount may be caused. For example, Japanese Patent Application Publication No. 2007-274012 proposes that an annular spacer be mounted between a wafer and a template for holding the wafer in order to suppress warping up of a wafer outer circumferential portion after polishing due to the occurrence of the difference in in-plane polishing amount (see claim 1, paragraph 0009, and the like of Japanese Patent Application Publication No. 2007-274012). However, control of the difference in an in-plane polishing amount by the spacer requires adjustment of the shape, the arrangement position, and the like of the spacer, and hence is not easy. Further, proper setting of polishing conditions may contribute to control of the difference in an in-plane polishing amount in wafer one side polishing. However, conventionally, a lot of trials and errors need to be repeated in order to find such polishing conditions.

It is an object of one aspect of the present invention to set proper polishing conditions and to enable easy control of the difference in an in-plane polishing amount in a wafer one side polishing step.

One aspect of the present invention is as follows.
[1]A method of determining polishing conditions under which a wafer one side is polished by a polishing device (which will be also hereinafter described as “polishing conditions determination method”),
   the polishing device including at least a surface plate, a polishing pad arranged on the surface plate, and a polishing chuck arranged above the polishing pad,
   the method including:
   setting a target range of a wafer polishing amount in-plane difference;
   determining a prediction range of a wafer polishing pressure in-plane difference predicted to be able to attain the wafer polishing amount in-plane difference within the target range on the basis of correlation between the wafer polishing amount in-plane difference and the wafer polishing pressure in-plane difference; and
   determining a pressing surface shape value range of the polishing chuck predicted to be able to attain the wafer polishing pressure in-plane difference within the prediction range on the basis of correlation between the wafer polishing pressure in-plane difference and the pressing surface shape value of the polishing chuck.
[2] The method of determining polishing conditions according to [1], in which the correlation between the wafer polishing amount in-plane difference and the wafer polishing pressure in-plane difference is a proportional relation.
[3] The method of determining polishing conditions according to [1] or [2], in which the pressing surface shape of the polishing chuck is a concave shape in which a central portion is more recessed than an outer circumferential portion relative to the polishing pad side, or a convex shape in which the central portion more protrudes than the outer circumferential portion relative to the polishing pad side, and
   the pressing surface shape value range to be determined falls within a recessing depth range of the concave shape or a protruding height range of the convex shape.
[4] The method of determining polishing conditions according to [3], in which the correlation between the wafer polishing pressure in-plane difference and the pressing surface shape value of the polishing chuck is a linear relation between the wafer polishing pressure in-plane difference and the recessing depth, or a linear relation between the wafer polishing pressure in-plane difference and the protruding height.
[5] The method of determining polishing conditions according to [3] or [4], further including determining the pressing surface shape of the polishing chuck by approximating a radial cross sectional shape to a quadratic function.
[6] The method of determining polishing conditions according to any of [3] to [5], in which the recessing depth range of the concave shape or the protruding height of the convex shape is determined on the basis of one or both of a thickness and a hardness of the polishing pad.
[7] The method of determining polishing conditions according to [6], further including:
   determining the thickness of the polishing pad for use in actual polishing; and
   determining the recessing depth range of the concave shape or the protruding height range of the convex shape within a narrower range in a case where the determined thickness of the polishing pad is thinner than a predetermined standard thickness.
[8] The method of determining polishing conditions according to [6] or [7], including:
   determining a hardness of the polishing pad for use in actual polishing; and,
   determining the recessing depth range of the concave shape or the protruding height range of the convex shape within a narrower range in a case where the determined hardness of the polishing pad is harder than a predetermined standard hardness.
[9]A method of manufacturing a wafer having a polished surface, the method including:
   determining polishing conditions with the method of determining polishing conditions according to any of [1] to [8]; and,
   polishing a wafer one side by a polishing device including a polishing chuck having a pressing surface having a shape within a determined pressing surface shape value range.
[10] The manufacturing method according to [9], in which the polishing chuck has a pressing surface having a concave shape with a recessing depth of 5 μm or more and 20 μm or less.
[11] The manufacturing method according to [9] or [10], in which the polishing device includes a polishing pad having a thickness of 0.864 mm±20%, and a Young's modulus of 0.27 MPa±20%.
[12] The manufacturing method according to any of [9] to [11], in which the wafer is a semiconductor wafer.
[13] The manufacturing method according to [12], in which the semiconductor wafer is a silicon wafer.
[14]A wafer one side polishing system, having:
   a polishing device including at least a surface plate, a polishing pad arranged on the surface plate, and a polishing chuck arranged above the polishing pad; and
   a polishing conditions determination part which determines polishing conditions by the method of determining polishing conditions according to any of [1] to [8].

In accordance with one aspect of the present invention, it becomes possible to set proper polishing conditions, and control the difference in an in-plane polishing amount with ease in the wafer one side polishing step.

### BRIEF DESCRIPTION OF DRAWINGS

FIG. 1 is a partial schematic cross sectional view of a polishing device.

FIG. 2 is a schematic cross sectional view of a polishing chuck in a concave shape (concave chuck) in which the pressing surface shape is more recessed at the central portion than at the outer circumferential portion with respect to the polishing pad side.

FIG. 3 is a schematic cross sectional view of a polishing chuck in a convex shape (convex chuck) in which the pressing surface shape more protrudes at the central portion than at the outer circumferential portion with respect to the polishing pad side.

FIG. 4 is a graph showing the in-plane distribution of each wafer polishing amount (actual measurement value) when a concave chuck is used and when a convex chuck is used.

FIG. 5 is a conceptual view of a two-dimensional axisymmetric model used for calculating the pressure to be applied to the surface to be polished of a wafer by simulation.

FIG. 6 is a graph showing the in-plane distribution of each pressure to be applied to the surface to be polished of the wafer when a concave chuck is used and when a convex chuck is used (actual measurement results and simulation).

FIG. 7 shows the circumferential average machining allowance GBIR and p_max−p_min.

FIG. 8 shows the results obtained by calculating the pressure to be applied to the surface to be polished of a wafer when polishing chucks in various pressing surface shapes are used by simulation.

FIG. 9 shows the results obtained by calculating the pressure to be applied to the surface to be polished of a wafer when polishing chucks in various pressing surface shapes are used by simulation.

FIG. 10 shows the results obtained by approximating the axial cross sectional shape by a quadratic function for the pressing surface of the polishing chuck.

FIG. 11 is a graph showing the thickness dependency and the hardness dependency of the polishing pad of the wafer polishing pressure in-plane difference.

### DESCRIPTION OF EMBODIMENTS

### [Polishing Conditions Determination Method]

One aspect of the present invention relates to a method of determining polishing conditions for polishing one side of a wafer by a polishing device.

The polishing device includes at least a surface plate, a polishing pad arranged on the surface plate, and a polishing chuck arranged above the polishing pad.

The polishing conditions determination method includes:
setting a target range of a wafer polishing amount in-plane difference;
determining the prediction range of the wafer polishing pressure in-plane difference predicted to be able to attain the wafer polishing amount in-plane difference within the target range on the basis of the correlation between the wafer polishing amount in-plane difference and the wafer polishing pressure in-plane difference; and
determining the pressing surface shape value range of the polishing chuck predicted to be able to attain the wafer polishing pressure in-plane difference within the prediction range on the basis of the correlation between the wafer polishing pressure in-plane difference and the pressing surface shape value of the polishing chuck.

As described in detail below, the present inventors newly found that the wafer polishing amount in-plane difference and the wafer polishing pressure in-plane difference are correlated with each other, and that the wafer polishing pressure in-plane difference and the pressing surface shape value of the polishing chuck are correlated with each other. With the method of determining the wafer polishing conditions, it is possible to determine the polishing conditions predicted to be able to readily attain the desired wafer polishing amount in-plane difference on the basis of the correlation thereof.

Below, the method of determining the wafer polishing conditions will be further described in detail. In the present invention and in the present description, the expressions “above”, “lower surface”, and the like mean “above”, “lower surface”, and the like when the polishing device is placed in a state in which a polishing treatment is performed, respectively. Below, although a description may be given by reference to the accompanying drawings, the embodiment shown in the drawing is illustrative, and the present invention is not limited to such an embodiment.

### <Polishing Target>

A wafer to be polished can be, for example, a semiconductor wafer. The semiconductor wafer can be, for example, a semiconductor wafer such as a single crystal silicon wafer. For example, a silicon wafer can be manufactured in the following manner. A single crystal silicon ingot is cut, resulting in a block. The single crystal silicon ingot can be grown by a known method such as the CZ method (Czochralski method), or the FZ method (floating zone melting (Floating Zone) method). The resulting block is sliced, resulting in a wafer. The wafer is subjected to various processing operations. As a result, a silicon wafer can be manufactured. Examples of the processing operations include chamfering processing, planarization processing (lapping, grinding, or polishing), and the like. The wafer one side polishing step whose polishing conditions are determined by the polishing conditions determination method is preferable as, for example, the polishing method at the finish polishing step that is the final step of the wafer processing operations.

### <Polishing Device>

### (Configuration Example Polishing Device)

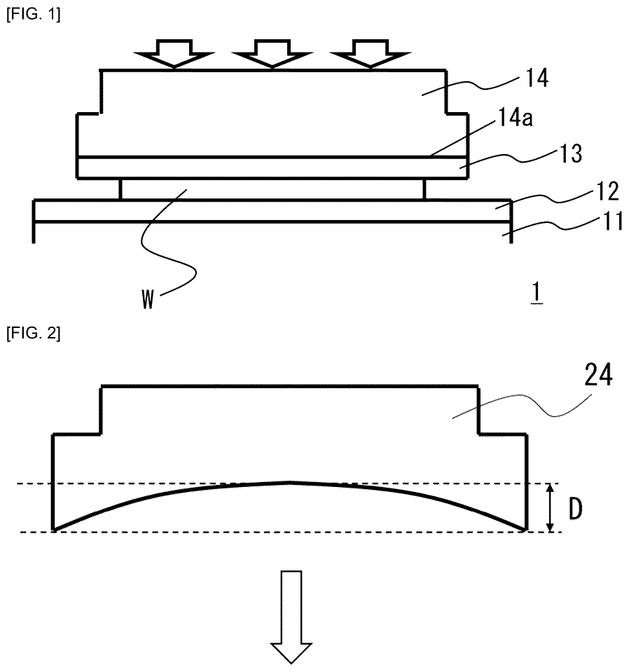

The polishing device is a wafer one side polishing device, and includes at least a surface plate, a polishing pad arranged on the surface plate, and a polishing chuck arranged above the polishing pad. FIG. 1 shows a partial schematic cross sectional view of one example of such a polishing device.

A polishing device 1 shown in FIG. 1 has a surface plate 11, a polishing pad 12, and a polishing chuck 14, and further has a back pad 13. An arrow in FIG. 1 schematically shows a state in which the upper portion of the polishing chuck 14 is pressurized.

The polishing device 1 brings the surface to be polished of a wafer W to be polished and the polishing pad 12 bonded on the surface plate 11 into sliding contact with each other while rotating the surface plate 11 and the polishing chuck 14 by a rotation mechanism (not shown), respectively. The abrasive discharged from an abrasive supply mechanism (not shown) of the polishing device is supplied to between the surface to be polished of the wafer W (the lower surface of the wafer W) and the polishing pad 12, so that the surface to be polished of the wafer W is polished. As the abrasive, a polishing slurry generally for use in CMP (chemical Mechanical Polishing) can be used.

The polishing chuck 14 can be a polishing chuck that includes a rigid body at a portion thereof including a lower surface 14a, or the entire body of the polishing chuck can be a rigid body. The rigid body can be, for example, ceramics. The lower surface 14a of the polishing chuck 14 is a pressing surface for pressing the wafer W via the back pad 13. With the polishing device 1, the back pad 13 is bonded with the pressing surface (lower surface) 14a of the polishing chuck 14. The back pad 13 can be bonded with the pressing surface 14a of the polishing chuck 14 by a known method such as use of an adhesive. As the back pad 13, for example, a disk-shaped sheet made of a material (for example, expandable polyurethane) showing adsorption property by the surface tension of water when it includes water can be used. As a result of this, it is possible to cause the back pad 13 which has included water upon polishing to hold the wafer W (so-called water spreading).

### (Pressing Surface Shape of Polishing Chuck)

In the polishing device 1 shown in FIG. 1, the surface shape of the pressing surface 14a of the polishing chuck 14 is a plane. However, in the polishing device for use in the wafer one side polishing step whose polishing conditions are determined by the polishing conditions determination method, the pressing surface shape of the polishing chuck is not limited to a plane, and, in one embodiment, can be in a concave shape in which the central portion is more recessed than the outer circumferential portion with respect to the polishing pad side, and, in another embodiment, can be in a convex shape in which the central portion more protrudes than the outer circumferential portion with respect to the polishing pad side. The pressing surface of the polishing chuck is generally circular in a plan view. It is assumed that the description regarding the shape in the present invention and the present description allows for the normally possible errors. For example, a circular shape is assumed to include even a shape with an error in shape caused from a circular shape within the range in which the error in shape can be generally caused at the time of manufacturing the polishing chuck, or at other times in addition to a perfect circular shape. Below, the polishing chuck with the pressing surface shape in a concave shape in which the central portion is more recessed than the outer circumferential portion with respect to the polishing pad side will be referred to as a “concave chuck”. The polishing chuck with the pressing surface shape in a convex shape in which the central portion more protrudes than the outer circumferential portion with respect to the polishing pad side will be referred to as a “convex chuck”.

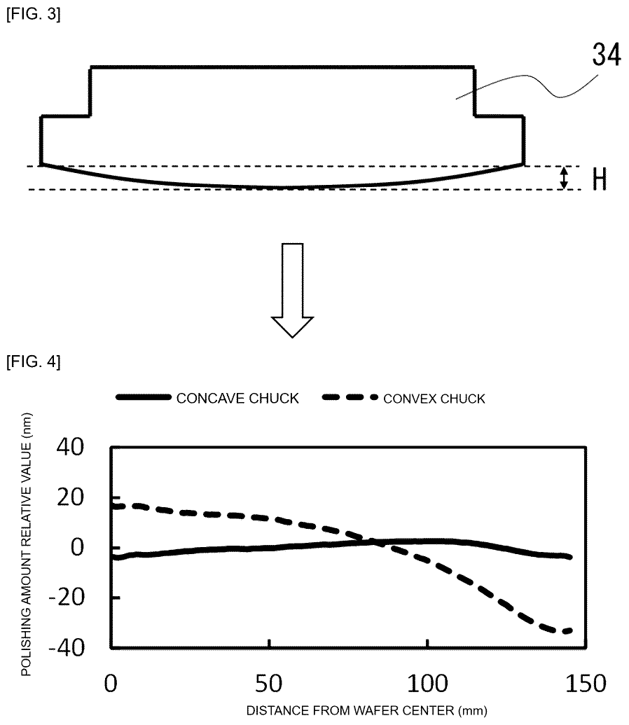

FIG. 2 is a schematic cross sectional view of a polishing chuck (concave chuck) 24 with the pressing surface shape in a concave shape in which the central portion is more recessed than the outer circumferential portion with respect to the polishing pad side. In FIG. 2, the direction indicated with an arrow is the polishing pad side. This point also applies to FIG. 3 described later. As for the concave shape, the “recessing depth” is the vertical distance between the central portion and the outer circumferential portion of the pressing surface, and is, for example, the depth D shown in FIG. 2. The recessing depth can fall within, for example, the range of more than 0 μm and 50 μm or less, and is not limited to this range.

FIG. 3 is a schematic cross sectional view of a polishing chuck (convex chuck) 34 with the pressing surface shape in a convex shape in which the central portion more protrudes than the outer circumferential portion with respect to the polishing pad side. As for the convex shape, the “protruding height” is the vertical distance between the central portion and the outer circumferential portion of the pressing surface, and is, for example, the height H shown in FIG. 3. The protruding height can fall within, for example, the range of more than 0 μm and 30 μm or less, and is not limited to this range.

### <Specific Example of Determination of Polishing Conditions>

In the course of an extensive study for setting proper polishing conditions, and enabling easy control of the difference in in-plane polishing amount in the wafer one side polishing step, the present inventors performed the following measurement and simulation.

The wafer one side polishing step of a silicon wafer with a diameter of 300 mm was carried out using a concave chuck and a convex chuck, respectively. The used concave chuck is a concave chuck with a recessing depth D of 10 μm shown in FIG. 2, and the used convex chuck is a convex chuck with a protruding height H of 2 μm shown in FIG. 3. As the polishing pad, a polishing pad with a thickness of 0.486 mm and a Young's modulus of 0.27 MPa was used.

FIG. 4 is a graph showing the in-plane distribution of the wafer polishing amount (relative value) of each of the case using a concave chuck and the case using a convex chuck. The polishing amount can be determined as the difference between the wafer thickness before polishing and the wafer thickness after polishing (“wafer thickness before polishing”−“wafer thickness after polishing”). In FIG. 4, the wafer polishing amount is shown as the relative value with reference to the target value of the wafer polishing amount. The graph shown in FIG. 4 can confirm that the polishing amount of the central portion is larger than the polishing amount of the outer circumferential portion when a convex chuck is used. Further, the graph shown in FIG. 4 can confirm that the difference in polishing amount in the wafer plane when a concave chuck is used is smaller as compared with the case using a convex chuck.

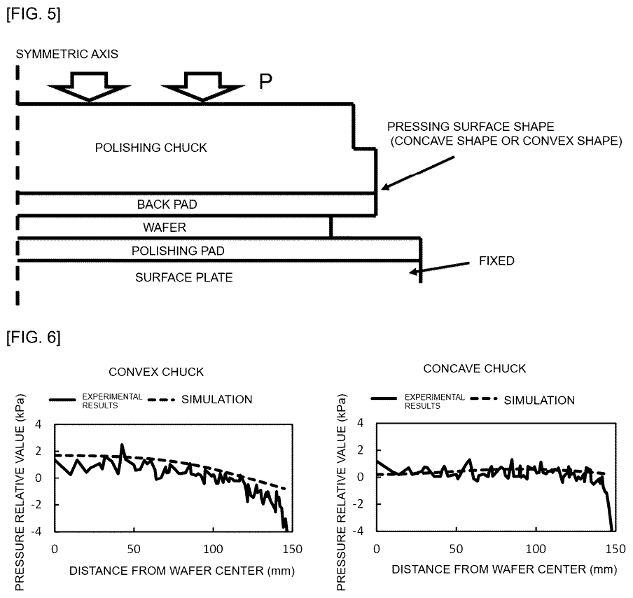

The present inventors calculated the pressure to be applied to the surface to be polished of the wafer for the state in which the polishing chuck is applied with a pressure P in the wafer one side polishing step using the concave chuck and the wafer one side polishing step using the convex chuck using a two-dimensional axisymmetric model whose conceptual view is shown in FIG. 5 by simulation. The simulation was performed for the case using a polishing pad with a thickness of 0.486 mm and a Young's modulus of 0.27 MPa. The simulation of the pressure was performed by pressure calculation (finite element method) using ABAQUS (general-purpose nonlinear structural analysis software) manufactured by DASSALT SYSTEMS Co.

Further, the pressure to be applied to the surface to be polished of the wafer was actually measured with the surface plate fixed and with the polishing chuck applied with the same pressure P as that in the simulation in the polishing device used at the previously described wafer one side polishing step using a commercially available surface pressure sheet. In the actual measurement, data was averaged with number of repeating measurements N=3, and further the pressure distribution averaged in the circumferential direction was determined.

FIG. 6 is a graph showing the in-plane distribution of the pressure to be applied to the surface to be polished of the wafer when a concave chuck is used and when a convex chuck is used (actual measurement results and simulation). In FIG. 6, the pressure is expressed as the relative value with reference to the pressure P. FIG. 6 can confirm that the calculation results with simulation roughly reproduce the actual measurement results. Further, FIGS. 4 and 6 can confirm that in the case using a concave chuck with a smaller difference in polishing mount within the wafer plane as compared with the case using a convex chuck, the difference in pressure within the wafer plane is also smaller than that in the case using a convex chuck.

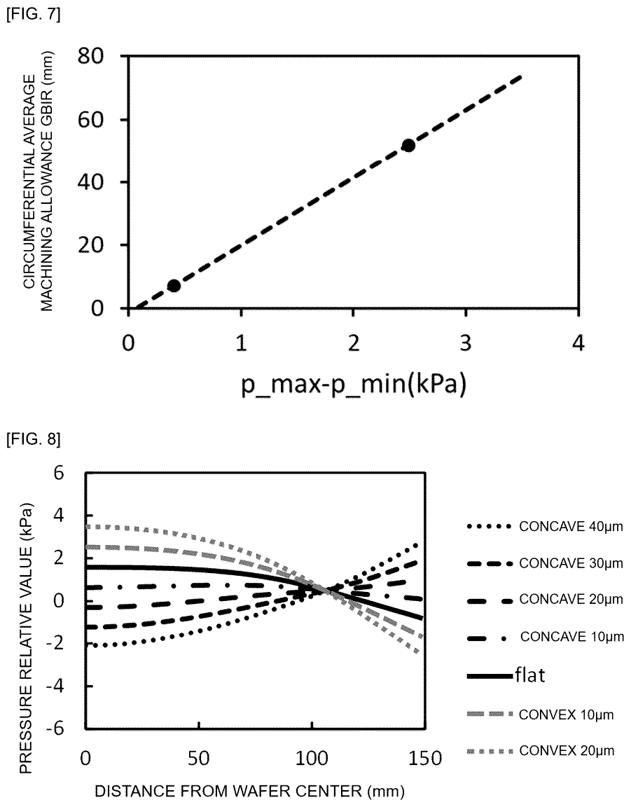

FIG. 7 shows the circumferential average machining allowance GBIR and the p_max−p_min. The circumferential average machining allowance GBIR of the vertical axis is the difference between the maximum value and the minimum value of the polishing amount resulting from the circumferential average of FIG. 4. The p_max−p_min of the horizontal axis is the difference between the maximum value and the minimum value of the pressure distribution obtained by the simulation shown in FIG. 6. In order to ensure sufficient simulation precision and measurement precision, for the calculation, data obtained by removing 5 mm from the end of the wafer was used. In FIG. 7, the left-side plot shows the results of the case using a concave chuck, and the right-side plot shows the results of the case using a convex chuck. FIG. 7 can confirm the following: the more uniform the pressure distribution within the wafer plane is, the more uniform the polishing amount within the wafer plane becomes.

The above results can confirm that the correlation exists between the wafer polishing amount in-plane difference and the wafer polishing pressure in-plane difference. The results shown in FIG. 7 can also confirm that the correlation can be the proportional relation. For example, on the basis of FIG. 7, when the target range of the wafer polishing amount in-plane difference is set at the “circumferential average machining allowance GBIR<30 nm”, the wafer polishing amount in-plane difference within this target range can be predicted to be able to be attained by setting the wafer polishing pressure in-plane difference at the “p_max−p_min<1.5 kPa”.

The present inventors further performed the following simulation in order to study the pressing surface shape dependency of the polishing chuck of the pressure distribution to be applied to the surface to be polished of the wafer regarding the wafer one side polishing step. For the simulation, using the two-dimensional axisymmetric model whose conceptual view is shown in FIG. 5, ABAQUS (general-purpose nonlinear structural analysis software) manufactured by DASSALT SYSTEMS Co., was used, and the pressure calculation was performed by the finite element method.

As for the wafer one side polishing step of a silicon wafer with a diameter of 300 mm, using the two-dimensional axisymmetric model whose conceptual view is shown in FIG. 5, polishing chucks in various pressing surface shapes were used. The pressure to be applied to the surface to be polished of the wafer when a polishing pad with a thickness of 0.486 mm and a Young's modulus of 0.27 MPa was used, was calculated by simulation. The simulation results are shown in FIG. 8.

The polishing chucks in various pressing surface shapes are:
a polishing chuck with a planar pressing surface shape (“flat” in FIG. 8 described later),
concave chucks with recessing depths D shown in FIG. 2 of 10 μm, 20 μm, 30 μm, and 40 μm (concave 10 μm, concave 20 μm, concave 30 μm, and concave 40 μm in FIG. 8), and
convex chucks with the protruding heights H shown in FIG. 3 of 10 μm, and 20 μm (convex 10 μm, and convex 20 μm in FIG. 8).

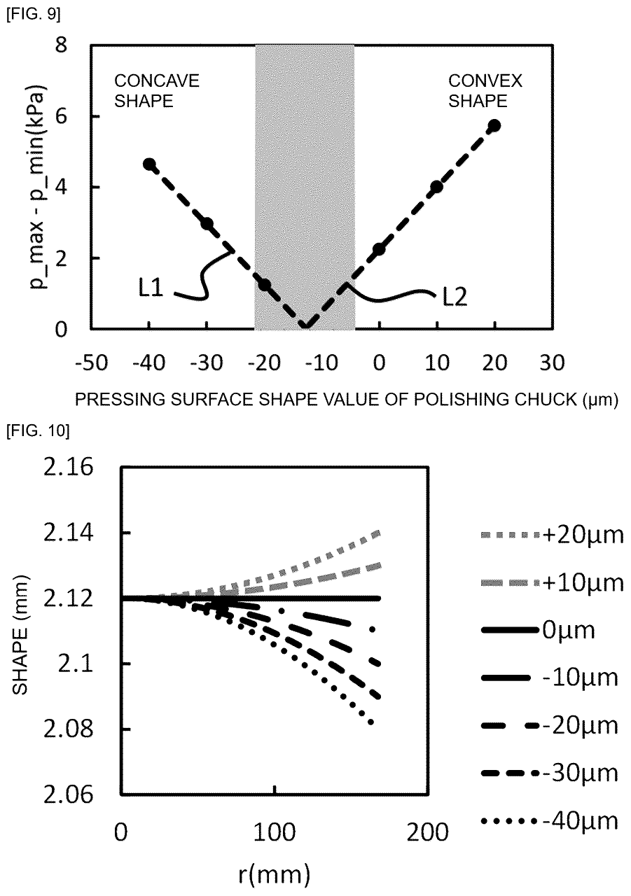

FIGS. 8 and 9 show the results of calculation of the pressure to be applied to the surface to be polished of a wafer when polishing chucks in various pressing surface shapes are used by simulation.

FIG. 8 is the in-plane distribution of the pressure obtained by calculation. As the pressing surface shape of the polishing chuck changes from the concave shape to the convex shape, the in-plane distribution of the pressure also changes with the similar tendency. In this manner, it can be confirmed that the wafer polishing pressure in-plane difference (for example, p_max−p_min) and the pressing surface shape value of the polishing chuck are correlated with each other.

FIG. 9 is a graph obtained by calculating p_max−p_min as previously described from the in-plane distribution of the pressure determined in conjunction with FIG. 8, and performing plotting for the pressing surface shape value of the polishing chuck. The pressing surface shape value is the recessing depth or protruding height, and 0 μm in the case of a flat surface. In FIG. 9, a dotted line L1 is a straight line passing through plots of 3 points at which the pressing surface shape value of the polishing chuck is −20 μm (concave 20 μm), the pressing surface shape value of the polishing chuck is −30 μm (concave 30 μm), and the pressing surface shape value of the polishing chuck is −40 μm (concave 40 μm). In FIG. 9, a dotted line L2 is a straight line passing through plots of 3 points at which the pressing surface shape value of the polishing chuck is 0 μm (flat), the pressing surface shape value of the polishing chuck is 10 μm (convex 10 μm), and the pressing surface shape value of the polishing chuck is 20 μm (convex 20 μm). FIG. 9 can confirm the following: it can be said that the wafer polishing pressure in-plane difference and the pressing surface shape value of the polishing chuck are correlated, and that a linear relationship holds. Specifically, it can be said that a linear relationship is present between the wafer polishing pressure in-plane difference and the recessing depth of the concave shape of the concave chuck, and it can be said that a linear relationship is present between the wafer polishing pressure in-plane difference and the protruding height of the convex shape of the convex chuck. More specifically, it can be said as follows: when the pressing surface shape value of the polishing chuck is from −13 μm to −40 μm, the linear relationship indicated with the dotted line L1 in FIG. 9 is present; and when the pressing surface shape value of the polishing chuck is from −13 μm to 0 μm, and from 0 μm to 20 μm, the linear relationship indicated with the dotted line L2 in FIG. 9 is present.

As described previously, for example, when the target range of the wafer polishing amount in-plane difference is set at the “circumferential average machining allowance GBIR<30 nm” on the basis of FIG. 7, the wafer polishing amount in-plane difference within the target range can be predicted to be attainable by setting the wafer polishing pressure in-plane difference at “p_max−p_min<1.5 kPa”. Further, on the basis of the linear relationship indicated with the dotted line L1 and the linear relationship indicated with L2 of FIG. 9, the prediction range of the wafer polishing pressure in-plane difference of “p_max−p_min<1.5 kPa” can be predicted to be attainable by using a concave chuck with a recessing depth of the concave shape of 4 μm or more and 21 μm or less (in FIG. 9, the pressing surface shape value of the polishing chuck within the range of from −4 μm to −21 μm).

In FIG. 9, the dotted line L1 and the dotted line L2 are shown as the straight lines passing through a plurality of plots. However, the linear relationship is not limited to such an example. For example, a plurality of plots are subjected to linear approximation by known fitting processing such as the least square method, thereby acquiring a linear function. Thus, the prediction can also be performed on the basis of the linear relationship expressed by the linear function.

In one embodiment, the pressing surface shape of the polishing chuck can be determined by approximating the radial cross sectional shape to a quadratic function. Such approximation by a quadratic function can be performed, for example, in the following manner.

As for the pressing surface (circular in a plane view) of the polishing chuck, the outermost circumferential position is set at a position of radius r=167.5 mm, and the vertical distance between the pressing surface center and the outermost circumferential position is set at the recessing depth of the concave shape for the concave chuck, and set at the protruding height of the convex shape for the convex chuck. Further, below, the protruding height is described as a positive (+) value, and the recessing depth is described as a negative (−) value. Each pressing surface shape of a plane, a protruding height of 10 μm, a protruding height of 20 μm, a recessing depth of 10 μm, a recessing depth of 20 μm, a recessing depth of 30 μm, and a recessing depth of 40 μm can be determined in the following manner: when the pressing surface shape value (specifically, the protruding height or the recessing depth) is determined, the vertical distance from the pressing surface center at each portion within the plane of the pressing surface is calculated as “y” using the following equation “y=a*r²+b” as the quadratic function, and the calculated value is applied to the two-dimensional axisymmetric model. In the equation, b represents the relative height or the relative depth. When the pressing surface shape value is assumed to be C, a can be determined by a=C/(167.5)². Specifically, a and b in the equation for calculating the shape of the pressing surface of the each pressing surface shape value become the values shown in Table 1 below, respectively. The expression such as “E-07” in Table 1 is an index expression as known. FIG. 10 shows the radial cross sectional shape of the pressing surface of the polishing chuck formed by plotting the calculated value of y calculated by the equation using a and b shown in Table 1 in the radial direction.

TABLE 1

| C | “+20 μm” | “+10 μm” | “0 μm” | “−10 μm” | “−20 μm” | “−30 μm” | “−40 μm” |
|---|---|---|---|---|---|---|---|
| a | 7.13E−07 | 3.56E−07 | 0.00E+00 | −3.56E−07 | −7.13E−07 | −1.07E−06 | −1.43E−06 |
| b | 2.12E+00 | 2.12E+00 | 2.12E+00 | 2.12E+00 | 2.12E+00 | 2.12E+00 | 2.12E+00 |

As described above, as a result of an extensive study by the present inventors, it has been newly found that the wafer polishing amount in-plane difference and the wafer polishing pressure in-plane difference are correlated with each other, and that the wafer polishing pressure in-plane difference and the pressing surface shape value of the polishing chuck are correlated with each other. On the basis of the correlations, according to the following procedure, the polishing conditions predicted to be able to attain the desirable wafer polishing amount in-plane difference can be determined with ease.

First, the target range of the wafer polishing amount in-plane difference is set. The target range of the wafer polishing amount in-plane difference can be set according to the quality required of the wafer to be manufactured through actual polishing. From the viewpoint of performing the wafer one side polishing step providing a smaller polishing amount in-plane difference, it is desirable to set the target range of the wafer polishing amount in-plane difference smaller. The actual polishing represents polishing to be actually performed for manufacturing a product.

After setting the target range, on the basis of the correlation between the wafer polishing amount in-plane difference and the wafer polishing pressure in-plane difference, the prediction range of the wafer polishing pressure in-plane difference predicted to be able to attain the wafer polishing amount in-plane difference within the target range is determined.

Further, subsequently, on the basis of the correlation between the wafer polishing pressure in-plane difference and the pressing surface shape value of the polishing chuck, the pressing surface shape value range of the polishing chuck predicted to be able to attain the wafer polishing pressure in-plane difference within the prediction range is determined.

For example, in one embodiment, with the thickness and the hardness of the polishing pad as specific values, it is possible to acquire the correlation information between the wafer polishing amount in-plane difference and the wafer polishing pressure in-plane difference (for example, a graph, or a relational expression), and the correlation information between the polishing pressure in-plane difference and the pressing surface shape value of the polishing chuck (for example, a graph, or a relational expression) by the simulation as described above. Then, on the basis of the acquired correlation information, according to the procedure described above, it is possible to determine the pressing surface shape value range of the polishing chuck predicted to be able to attain the desirable wafer polishing amount in-plane difference.

Further, in one embodiment, further, it is possible to determine the pressing surface shape value range of the polishing chuck on the basis of one of the thickness and the hardness of the polishing pad. This point will be further described in detail below.

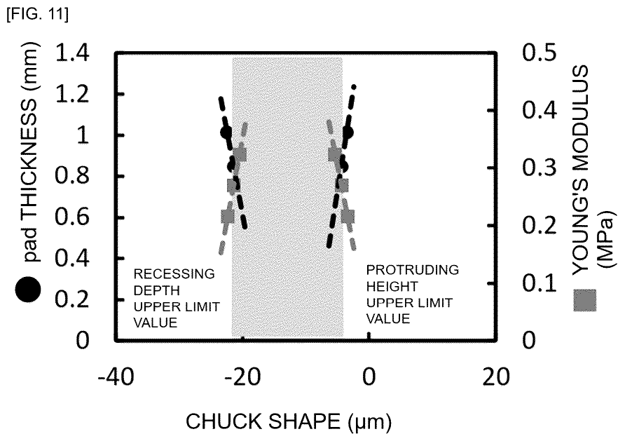

FIG. 11 is a graph showing the thickness dependency and the hardness dependency of the polishing pad of the wafer polishing pressure in-plane difference. FIG. 11 is a graph formed in the following manner.

The simulation previously described was performed for the case using a polishing pad with a thickness (hereinbelow, “standard thickness”) of 0.486 mm, and a Young's modulus (hereinbelow, “standard hardness”) of 0.27 MPa. The simulation previously described was carried out by changing the thickness or the hardness (specifically, the Young's modulus) of the polishing pad. Specifically, the distribution of the pressure to be applied to the wafer when the thickness and the Young's modulus of the polishing pad are allocated to their respective standard values (the standard thickness, and the standard hardness)±20% was calculated, and the upper limit values of the recessing depth and the protruding height resulting in p_max−p_min=1.5 kPa were plotted in FIG. 11.

As shown in FIG. 11, the thinner the thickness of the polishing pad becomes, and the harder the hardness of the polishing pad becomes, the range of the pressing surface shape value (the recessing depth or the protruding height) of the polishing chuck resulting in “p_max−p_min<1.5 kPa” narrows. In the example shown in FIG. 11, the range of the pressing surface shape value of the polishing chuck resulting in “p_max−p_min<1.5 kPa” is 5 μm or more and 20 μm or less for a concave shape.

The above results can confirm the following: the thinner the thickness of the polishing pad is, the pressing surface shape value range of the polishing chuck predicted to be able to attain the wafer polishing pressure in-plane difference within the prediction range is preferably set within a narrower range. Further, the harder the hardness of the polishing pad is, the pressing surface shape value range of the polishing chuck predicted to be able to attain the wafer polishing pressure in-plane difference within the prediction range is preferably set within a narrower range.

Therefore, for example, when the determined thickness of the polishing pad is thinner than the predetermined standard thickness after determining the thickness of the polishing pad for use in actual polishing, the recessing depth range of the concave shape of the concave chuck, or the protruding height range of the convex shape of the convex chuck can be determined within a narrower range. For example, when the determined hardness of the polishing pad is harder than the predetermined standard hardness after determining the hardness of the polishing pad for use in actual polishing, the recessing depth range of the concave shape of the concave chuck, or the protruding height of the convex shape of the convex chuck can be determined within a narrower range. The standard thickness and the standard hardness can be, for example, the thickness and the hardness adopted in the simulation for acquiring the correlation information previously described.

### <Method of Manufacturing Wafer Having Polished Surface>

One aspect of the present invention relates to a method of manufacturing a wafer having a polished surface, including: determining the polishing conditions by the polishing conditions determination method; and polishing a wafer one side by a polishing device including a polishing chuck having a pressing surface in a shape within the determined pressing surface shape value range.

To the manufacturing method, it is possible to apply a known technology regarding the method of manufacturing a wafer having a polished surface except for polishing the wafer one side by a polishing device including a polishing chuck having a pressing surface in a shape within the pressing surface shape value range determined as described previously. As for the wafer to be polished, the configuration of the polishing device, the polishing treatment, and the like, a reference can be made to the previous description.

In one embodiment of the manufacturing method, it is possible to use a polishing chuck having a pressing surface in a concave shape with a recessing depth of 5 μm or more and 20 μm or less on the basis of the previously described determination results. Whereas, in another embodiment, it is possible to use a polishing pad with a thickness of 0.864 mm±20%, and a Young's modulus of 0.27 MPa±20% as the polishing pad on the basis of the previously described simulation results.

Further, a still other aspect of the present invention relates to a method of manufacturing a wafer having a polished surface, including polishing the wafer one side by a polishing device including a polishing chuck having a pressing surface in a concave chape with a recessing depth of 5 μm or more and 20 μm or less, and a polishing pad with a thickness of 0.864 mm±20%, and a Young's modulus of 0.27 MPa±20%. For the details of such a manufacturing method, reference can be made to the previous description.

### <Wafer One Side Polishing System>

A still further aspect of the present invention relates to a wafer one side polishing system having a polishing device including at least a surface plate, a polishing pad arranged on the surface plate, and a polishing chuck arranged above the polishing pad, and a polishing conditions determination part which determines polishing conditions by the polishing conditions determination method.

With the polishing conditions determination part, for example, when the target range of the wafer polishing amount in-plane difference is inputted, the pressing surface shape value range of the polishing chuck predicted to be able to attain the wafer polishing pressure in-plane difference within the prediction range can be determined from the correlation information (for example, the graph or the relational expression) between the wafer polishing amount in-plane difference and the wafer polishing pressure in-plane difference acquired as described previously, and the correlation information (for example, the graph or the relational expression) between the polishing pressure in-plane difference and the pressing surface shape value of the polishing chuck. Whereas, further, on the basis of one or both of the thickness and the hardness of the polishing pad, it is possible to determine the pressing surface shape value range of the polishing chuck predicted to be able to attain the wafer polishing pressure in-plane difference within the prediction range. Various calculations for determining the pressing surface shape value range of the polishing chuck can be performed using known calculation software.

With the system, the pressing surface shape value of the polishing chuck can be determined at the polishing condition determination part. Further, by approximating the radial cross sectional shape to a quadratic function as described previously, it is also possible to determine the pressing surface shape of the polishing chuck. For example, the polishing chuck having the pressing surface shape thus determined is selected from among a plurality of polishing chucks, and is mounted on a polishing device automatically or manually. As a result, the wafer one side polishing step can be carried out.

One aspect of the present invention is useful in the technical field of semiconductor wafers such as silicon wafers.

1. A method of determining polishing conditions under which a wafer one side is polished by a polishing device,
the polishing device comprises at least a surface plate, a polishing pad arranged on the surface plate, and a polishing chuck arranged above the polishing pad,
the method comprising:
setting a target range of a wafer polishing amount in-plane difference;
determining a prediction range of a wafer polishing pressure in-plane difference predicted to be able to attain the wafer polishing amount in-plane difference within the target range on the basis of correlation between the wafer polishing amount in-plane difference and the wafer polishing pressure in-plane difference; and
determining a pressing surface shape value range of the polishing chuck predicted to be able to attain the wafer polishing pressure in-plane difference within the prediction range on the basis of correlation between the wafer polishing pressure in-plane difference and the pressing surface shape value of the polishing chuck.

2. The method of determining polishing conditions according to claim 1,
wherein the correlation between the wafer polishing amount in-plane difference and the wafer polishing pressure in-plane difference is a proportional relation.

3. The method of determining polishing conditions according to claim 1,
wherein the pressing surface shape of the polishing chuck is a concave shape in which a central portion is more recessed than an outer circumferential portion relative to a polishing pad side, or a convex shape in which the central portion more protrudes than the outer circumferential portion relative to the polishing pad side, and
the pressing surface shape value range to be determined falls within a recessing depth range of the concave shape or a protruding height range of the convex shape.

4. The method of determining polishing conditions according to claim 3,
wherein the correlation between the wafer polishing pressure in-plane difference and the pressing surface shape value of the polishing chuck is a linear relation between the wafer polishing pressure in-plane difference and the recessing depth, or a linear relation between the wafer polishing pressure in-plane difference and the protruding height.

5. The method of determining polishing conditions according to claim 3, further comprising determining the pressing surface shape of the polishing chuck by approximating a radial cross sectional shape to a quadratic function.

6. The method of determining polishing conditions according to claim 3,
wherein the recessing depth range of the concave shape or the protruding height of the convex shape is determined on the basis of one or both of a thickness and a hardness of the polishing pad.

7. The method of determining polishing conditions according to claim 6, further comprising:
determining the thickness of the polishing pad for use in actual polishing; and
determining the recessing depth range of the concave shape or the protruding height range of the convex shape within a narrower range in a case where the determined thickness of the polishing pad is thinner than a predetermined standard thickness.

8. The method of determining polishing conditions according to claim 6, further comprising:
determining a hardness of the polishing pad for use in actual polishing; and,
determining the recessing depth range of the concave shape or the protruding height range of the convex shape within a narrower range in a case where the determined hardness of the polishing pad is harder than a predetermined standard hardness.

9. A method of manufacturing a wafer having a polished surface, the method comprising:
determining polishing conditions with the method of determining polishing conditions according to claim 1; and,
polishing a wafer one side by a polishing device comprising a polishing chuck having a pressing surface, the pressing surface having a shape within a determined pressing surface shape value range.

10. The manufacturing method according to claim 9,
wherein the polishing chuck has a pressing surface having a concave shape with a recessing depth of 5 μm or more and 20 μm or less.

11. The manufacturing method according to claim 9,
wherein the polishing device comprises a polishing pad having a thickness of 0.864 mm±20%, and a Young's modulus of 0.27 MPa±20%.

12. The manufacturing method according to claim 9,
wherein the wafer is a semiconductor wafer.

13. The manufacturing method according to claim 12,
wherein the semiconductor wafer is a silicon wafer.

14. A wafer one side polishing system, comprising:
a polishing device comprising at least a surface plate, a polishing pad arranged on the surface plate, and a polishing chuck arranged above the polishing pad; and
a polishing conditions determination part which determines polishing conditions by the method of determining polishing conditions according to claim 1.
